(19) United States
(12) Patent Application Publication
(10) Pub. No.: US 2025/0265402 A1
(43) Pub. Date: Aug. 21, 2025

(54) Topology of Integrated Clock Gate (ICGs) for Reduction of Sequential Depth by Coalescence of Flip-Flops Having a Low-Depth Fan-In Cone and a High-Depth Fan-Out Cone

(71) Applicant: Google LLC, Mountain View, CA (US)

(72) Inventors: Rajesh Arimilli, Bangalore (IN); Karthik Naishathrala Jayaraman, Bangalore (IN)

(73) Assignee: Google LLC, Mountain View, CA (US)

(21) Appl. No.: 19/199,037

(22) Filed: May 5, 2025

Related U.S. Application Data
(60) Provisional application No. 63/795,059, filed on Apr. 25, 2025.

(51) Int. Cl. G06F 30/333

(52) U.S. Cl. CPC G06F 30/333

(57) ABSTRACT

This document describes technology for sequential logic circuitry with a topology of integrated clock gates (iCGs) that reduces clock logic depth by coalescing flip-flops with a low-depth fan-in cone and a high-depth fan-out cone. This technology includes sequential logic circuitry, including a first group of one or more flip-flops, which is coupled to and driven by a first cluster of one or more iCGs. The sequential logic further includes a first group of one or more target flip-flops, each target flip-flop having a low-depth fan-in cone and a high-depth fan-out cone and a first cluster of one or more clone iCGs coupled to the first group of target flip-flops and the first cluster of one or more iCGs. The first cluster of one or more clone iCGs configured to coalesce with the first cluster of one or more iCGs and drive the first group of one or more target flip-flops.

### CROSS-REFERENCE TO RELATED APPLICATION

This application claims the benefit of U.S. Provisional Patent Application Ser. No. 63/795,059 filed on Apr. 25, 2025, the disclosure of which is incorporated by reference herein in its entirety.

### SUMMARY

This document describes technology for sequential logic circuitry with a topology of integrated clock gates (iCGs) that reduces clock logic depth by coalescence of flip-flops having low-depth fan-in cones and a high-depth fan-out cone. This technology includes sequential logic circuitry that includes a first group of one or more flip-flops that is coupled to and driven by a first cluster of one or more iCGs. The sequential logic further includes a first group of one or more target flip-flops, each target flip-flop having a low-depth fan-in cone and a high-depth fan-out cone and a first cluster of one or more clone iCGs coupled to the first group of target flip-flops and to the first cluster of one or more iCGs. The first cluster of one or more clone iCGs is configured to coalesce with the first cluster of one or more iCGs and drive the first group of one or more target flip-flops.

For example, a method is described that expands a clock window for the first group of one or more target flip-flops to enable complete signal propagation across the fan-out cone in one clock cycle. This document also describes computer-readable media having instructions for performing the above-summarized method and other methods set forth herein, as well as systems and means for performing these methods.

This summary is provided to introduce simplified concepts for a technology that utilizes a topology of iCGs that reduces clock logic depth by coalescing flip-flops with a low-depth fan-in cone and a high-depth fan-out cone. This technology is further described below in the Detailed Description and Drawings. This summary is not intended to identify essential features of the claimed subject matter, nor is it intended for use in determining the scope of the claimed subject matter.

### BRIEF DESCRIPTION OF THE DRAWINGS

The details of one or more aspects of technology that utilize sequential logic circuitry with a topology of integrated clock gates (iCGs) that reduces clock logic depth by coalescing flip-flops with a low-depth fan-in cone and a high-depth fan-out cone are described in this document with reference to the following drawings. The same numbers are used throughout the drawings to reference like features and components:

FIG. 1 illustrates an example operating environment in which a topology of integrated clock gates (iCGs) can be implemented in according with the technology described herein to reduce the clock logic depth of sequential logic circuitry in a digital circuit by coalescing flip-flops with a low-depth fan-in cone and a high-depth fan-out cone.

FIG. 2 illustrates an example of typical sequential logic circuitry, featuring a subject flip-flop with a low-depth fan-in cone and a high-depth fan-out cone.

FIG. 3 illustrates an example of sequential logic circuitry—featuring a target flip-flop with a low-depth fan-in cone and a high-depth fan-out cone—suitable for implementing the technology described herein to reduce the clock logic depth by coalescing flip-flops with a low-depth fan-in cone and a high-depth fan-out cone.

FIG. 4 illustrates example clock waveforms of clock signals that may be generated in accordance with the technology described herein.

FIG. 5 illustrates an example method 500 for expanding a clock window to enable complete signal propagation across a fan-out cone in one clock cycle in accordance with one or more implementations described herein to reduce the clock logic depth of sequential logic circuitry in a digital circuit by coalescing flip-flops with a low-depth fan-in cone and a high-depth fan-out cone.

### DETAILED DESCRIPTION

### Overview

A technology described herein is a topology of integrated clock gates (iCGs) that reduces the clock logic depth of sequential logic circuitry of a digital circuit by coalescing flip-flops with a low-depth fan-in cone and a high-depth fan-out cone. The technology described herein reduces the clock logic depth (e.g., reduction of the clock buffers leading to the flip-flops) of the sequential logic circuitry in the digital circuit. This decreases the Clock-to-Input Delay (CID) through clock pull and allocates more time for combinational logic of the digital circuit. This leads to improved Power-Performance-Area (PPA) metrics and simplifies Clock Tree Synthesis (CTS). Accordingly, this technology provides savings in power consumption and buffer requirements in the digital circuit.

Digital circuits divide into two main categories: combinational logic and sequential logic. Combinational logic produces outputs based solely on the current inputs through logic components such as AND, OR, and XOR gates. Sequential logic retains information over time using memory elements.

Sequential logic circuitry includes both combinational logic and memory elements, commonly referred to as flip-flops or, simply, “flops.” The flip-flop stores one bit of information and changes state based on clock signals. Multiple flip-flops connect in sequence to form registers, counters, and state machines. Each flip-flop captures data at specific clock transitions and maintains values until the next relevant clock event.

Clock logic depth (e.g., “stages” or “levels”) refers to the number of logic gates or elements that a clock signal must pass through before reaching all the flip-flops or memory elements in a circuit. High clock logic depth can lead to timing issues like clock skew, where the clock signal arrives at different parts of the circuit at different times.

The fan-in cone represents a network of all logic paths feeding into a specific flip-flop. This network includes source flip-flops, combinational logic gates, and primary inputs that affect the data input of the specific flip-flop. Fan-in cones define timing paths that complete within a clock cycle. The fan-out cone includes a network of all logic paths driven by the output of a source flip-flop. This network includes destination flip-flops, combinational logic gates, and primary outputs affected by the state of the source flip-flops. Fan-out cones determine signal loading effects and influence driving strength requirements.

Integrated clock gates (iCGs) control clock distribution to groups of flip-flops. These components block clock signals to inactive circuit sections, thereby reducing power consumption. Clock-to-Input Delay (CID) measures the timing between the arrival of a clock signal and a change in data input. This parameter can affect timing constraints throughout the digital circuit.

A clock window is the valid time period when flip-flops can reliably capture data. Clock windows directly affect circuit timing requirements. Narrower windows limit the time for data stabilization. Wider windows provide more margin for timing variations.

Clock pull is a timing optimization technique that deliberately improves clock delay (e.g., reduces clock delay) to specific flip-flops in digital circuits. This controlled reduction in clock delay creates additional time for data signals to reach target flip-flops before clock edges arrive. That is, the clock pull technique expands the clock window.

Power, Performance, and Area (PPA) metrics evaluate digital circuit quality. Lower power consumption, higher performance speed, and smaller silicon area indicate better digital circuits. Trade-offs between these factors drive many digital circuit implementation decisions.

A critical path (CP) represents the longest timing path through the circuit. This path limits the maximum operating frequency of the entire system. Critical paths often traverse multiple levels of logic and several flip-flop stages.

Clock Tree Synthesis (CTS) builds a network that distributes clock signals to all sequential elements. This process balances delays to minimize timing variations between different circuit sections. Proper clock distribution ensures synchronized operation across all components. Clock Tree Synthesis tools creates a clock network and balances the clock across all the sequential elements.

### Operating Environment

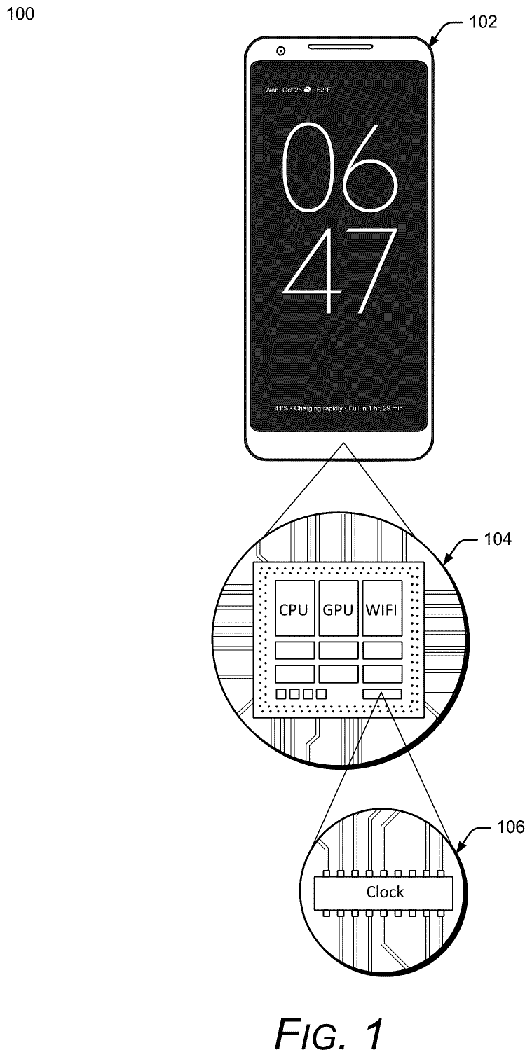

FIG. 1 illustrates an example operating environment 100 in which a topology of integrated clock gates (iCGs) can be implemented according to the technology described herein to reduce the clock logic depth of sequential logic circuitry in a digital circuit by coalescing flip-flops with a low-depth fan-in cone and a high-depth fan-out cone. The operating environment 100 includes user equipment 102 (e.g., a smartphone, mobile device, wearable device, tablet, or computing device). The user equipment 102 includes one or more digital circuits 104, which include components such as a clock 106.

Each of the one or more digital circuits 104 includes, for example, electronic components fabricated on a single piece of semiconductor material. Such circuits 104 contain multiple electronic elements combined into a unified topology. Examples of implementations of the digital circuits 104 include, but are not limited to, system on a chip (SoC), microcontroller units (MCUs), field programmable gate arrays (FPGAs), application specific integrated circuits (ASICs), graphics processing units (GPUs), digital processing units (DPUs), memory management units (MMUs), or a combination thereof.

As shown in FIG. 1, the implementation of the digital circuits 104 is a SoC, which incorporates all necessary electronic components of a computer or other electronic system into a single microchip. As shown, the SoC may include at least one central processing unit (CPU), a GPU, a Wi-Fi™ unit, and/or other components (which are not shown).

The clock 106 generates regular timing pulses that coordinate operations across one or more digital circuits 104. Clock signals alternate between high and low voltage levels at fixed intervals. Each clock cycle consists of one complete high-low transition. The clock frequency determines the number of cycles that occur per second. Clock signals provide synchronization for all sequential logic operations. These signals trigger state changes in flip-flops at specific transition points. Typically, a digital circuit captures data at rising clock edges when the voltage changes from low to high. The clock establishes when data values move between sequential stages (e.g., levels).

Clock distribution typically occurs through dedicated wiring networks. The main clock source branches into progressively smaller paths reaching each flip-flop. Ideally, the clock network delivers signals with minimal timing variations between different circuit locations. Clock buffers strengthen signals throughout this distribution path. Clock gating (e.g., with iCGs) blocks clock signals from reaching inactive circuit sections. This technique saves power by preventing unnecessary state changes. Dynamic power consumption decreases when flip-flops remain stable without clock transitions.

Clock signals impose timing constraints on the computation of combinational logic. As a result, clock signals ensure all computations receive closure before the subsequent clock transition. Beyond this timing control, the clock period also regulates the maximum permissible processing time between stages. Due to this association, clock frequency directly influences the performance and throughput capability in a circuit.

### Typical Sequential Circuitry

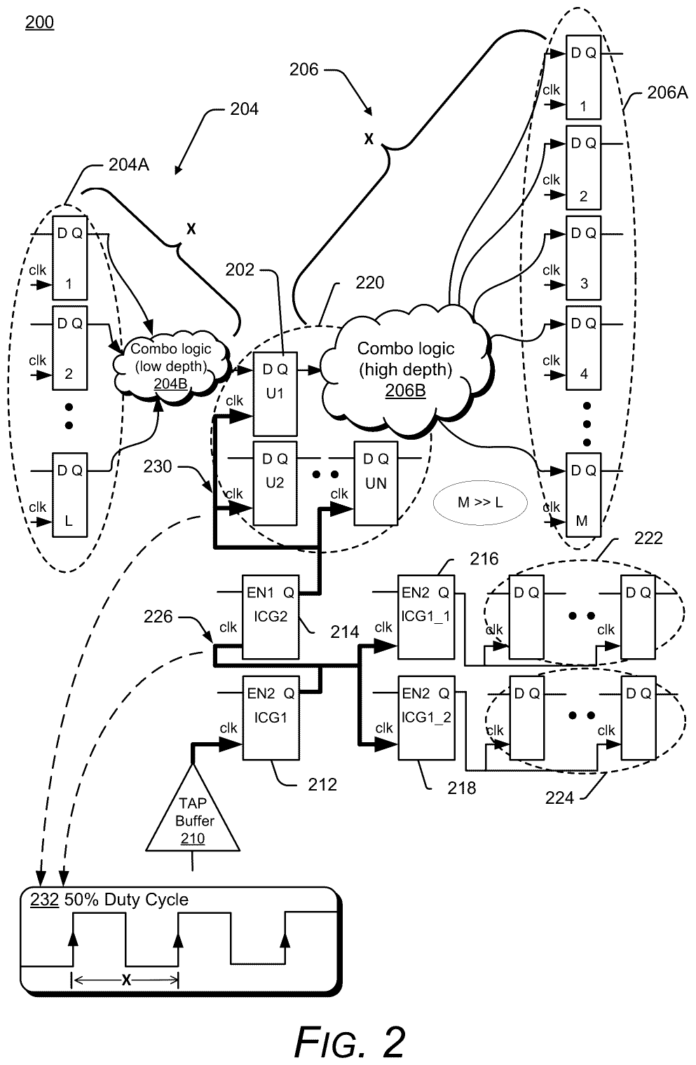

FIG. 2 illustrates an example of typical sequential logic circuitry 200, featuring a subject flip-flop 202 with a low-depth fan-in cone 204 and a high-depth fan-out cone 206. With typical sequential logic circuitry, a fundamental timing problem arises when the subject flip-flop 202 has minimal logic preceding it (e.g., low-depth fan-in cone 204) but extensive logic following it (e.g., high-depth fan-out cone 206). This potentially creates an unbalanced distribution of processing time around the subject flip-flop 202. This figure illustrates how such sequential logic circuitry typically operates without the technology described herein.

To the extent possible, the labeling of the sequential logic circuitry 200 adheres to standard electronic component marking conventions. To that end, each flip-flop is uniformly depicted as a vertical rectangle with an input terminal labeled “D” on its upper left side, an output terminal labeled “Q” on its upper right side, and an input control signal terminal labeled “clk” on its lower left side.

The “D” label on a flip-flop input stands for “Data.” This terminal receives a binary value (0 or 1) that will be stored in the flip-flop. The D input accepts a new state that the flip-flop should adopt at the next clock edge. In D flip-flops, whatever logic value exists at the D input during the active clock edge is transferred to the output.

The “Q” output label derives from historical naming conventions in electronic design. Q represents a current state stored by the flip-flop. This terminal outputs the binary value currently held in an internal storage of a flip-flop.

The clock (clk) input on a flip-flop controls when data sampling occurs. This input receives a regular timing signal (e.g., a clock signal) that alternates between high and low voltage levels. Flip-flops capture data at specific clock transitions. For example, a flip-flop may sample the D input value at the rising edge of the clock signal. The sampled value then appears at the Q output after a small propagation delay.

The subject flip-flop 202 serves as the primary point of reference for discussing the operation of this typical sequential logic circuitry 200. The subject flip-flop 202 features the low-depth fan-in cone 204 for its D input and the high-depth fan-out cone 206 for its Q output.

The fan-in cone 204 includes the logic paths that feed into the input of the subject flip-flop 202. As depicted, the fan-in cone 204 includes source flip-flops 204A, combinational logic 204B, and primary inputs that affect the data input D of the subject flip-flop 202. The source flip-flops 204A are numbered 1−L, where L is more than two. The number L represents the effective depth or levels of flip-flops in the fan-in cone 204.

The term “cone” refers to the way a network expands when traced backward from a target point, which is the subject flip-flop 202. Each logic path within the cone represents a potential route for signal propagation.

More specifically, the fan-in cone 204 is described as having low depth because it contains minimal logic levels between source and destination points (e.g., source is flip-flops 204A and destination is input D of subject flip-flop 202). Such configurations feature short paths with few gates connected in series between flip-flops. The limited depth results in reduced signal propagation delays and improved timing characteristics.

The fan-in cone 204 has a bracket labeled X, which is one clock period of a signal. A clock period contains one high pulse and one low pulse. The percentage of time a clock signal stays high during one complete period is called the duty cycle. Graph 232 illustrates a 50% duty cycle, which is the typical duty cycle of most digital circuits. As indicated in Graph 232, the signals propagate through the fan-in cone 204 during one complete clock signal period with a typical 50% duty cycle.

The fan-out cone 206 includes the logic paths extending forward from the output Q of the subject flip-flop 202. As depicted, the fan-out cone 206 includes destination flip-flops 206A, combinational logic 206B, and primary outputs affected by the output Q of the subject flip-flop 202. The destination flip-flops 206A are numbered 1−M, where M is more than L. That is, M is greater than L and something much greater than L (e.g., M>>L). The number M is representative of the effective depth or levels of flip-flops in the fan-out cone 206.

More specifically, the fan-out cone 206 is described as high-depth because it contains numerous logic levels between source and destination points (e.g., source is output Q of subject flip-flop 202 and destination includes flip-flops 206A). High-depth configurations feature long paths with many gates connected in series after the driving flip-flop. Typically, the extended depth results in increased signal propagation delays and challenging timing characteristics.

Like the fan-in cone 204, the fan-out cone 206 has a bracket labeled X for one clock period of a signal. As indicated in Graph 232, the signals propagate through the fan-out cone 206 during one complete clock signal period with a typical 50% duty cycle. However, because the path through the fan-out cone 206 includes many more layers of electronic components, the propagation takes longer.

With this arrangement, data arrives quickly at the subject flip-flop 202 through the low-depth fan-in cone 204. After capture, signals must travel through numerous logic gates of the high-depth fan-out cone 206 before reaching subsequent storage elements, such as flip-flops 206A. Digital circuits operate on clock cycles with strict timing requirements. All combinational logic between consecutive flip-flops completes processing within one clock period. However, with typical approaches, the extensive fan-out logic of the high-depth fan-out cone 206 exceeds this time budget.

As a result, the entire digital circuit must operate at a slower frequency to accommodate the longest path of the high-depth fan-out cone 206. This limitation reduces maximum throughput and decreases overall digital circuit performance. Circuit designers attempt to resolve this issue by inserting additional pipeline stages. Extra flip-flops divide the long combinational path into shorter segments. This solution requires additional clock cycles but enables operation at higher frequencies. Each added stage increases latency but can improve maximum clock speed.

The subject flip-flop 202 has a unit designation of “U1.” Indeed, it is one of a collection 220 of linked flip-flops having a similar unit designation that starts with “U” followed by a numerical identifier. The letter “U” before flip-flop identifiers indicates a unit designation in circuit schematics. The U-labeling follows standard electronic component marking conventions. As shown, there are N U-labeled flip-flops, where N is a number greater than two.

The U-labeled flip-flops in FIG. 2 share a common source of their clock signal 208. Because of this, each of the U-labeled flip-flops is synchronized. The shared clock signal 208 ensures that all connected flip-flops (e.g., U-labeled flip-flops) sample input data simultaneously.

Turning to the bottom of FIG. 2, the sequential logic circuitry 200 has a TAP (Test Access Port) buffer 210 connected to iCG1 212. The TAP 210 operates as a signal conditioning element, with its primary function being to receive input signals and produce strengthened output signals with maintained integrity. The TAP buffer 210 strengthens the clock signal before delivery to iCG1 212. The iCG1 212 is an integrated clock gate (iCG), which receives two primary inputs: a clock signal from the TAP buffer 210 and an enable signal EN2. The enable signal EN2 determines whether the clock signal passes through the iCG1 212. When the enable signal EN2 is active, the iCG1 212 allows the clock signal to pass through to the output, which is labeled Q.

As depicted, Q output of the iCG1 212 distributes clock signals 226 to three secondary clock gates. These secondary gates include iCG2 214, iCG1_1 216, and iCG1_218. This arrangement forms a hierarchical clock distribution network. As the primary clock gate, iCG1 212 controls whether any clock signals 226 reach the secondary gates. Each secondary gate then independently manages clock signal delivery to specific flip-flop groups. Each secondary gate contains a separate enable input. Clock signals pass through a secondary gate only under two conditions. First, the iCG1 212 must supply incoming clock pulses. Second, the secondary gate must receive an active enable signal. This multi-level structure provides graduated control over different circuit sections. The iCG1 212 enables or disables larger functional blocks. Secondary gates control smaller sub-sections within these blocks.

As depicted, the iCG2 214 manages clock signal 230 delivery to the U-labeled flip-flop collection 220, which includes the subject flip-flop 202. The iCG2 214 receives an enable signal EN1 to determine whether the clock signal passes through it. The iCG1_1 216 manages clock signal delivery to multiple downstream flip-flops 222 and iCG1_2 218 manages clock signal delivery to multiple downstream flip-flops 224. The enable signal EN1 determines whether the clock signal passes through the iCG1_1 216 and iCG1_2 218.

The control logic (not shown) of the sequential logic circuitry 200 supplies the enable signals EN1 and EN2 in response to circuit activity demands. The enable signal EN1 turns on or off the iCG2 214, iCG1_1 216 and iCG1_2 218. The enable signal EN2 turns on or off the iCG1 212. The Q output of the iCG1 212 passes clock signals only when both the clock signal from the TAP buffer 210 and the enable signal EN2 are active.

As shown by Graph 232, the clock signals 226 and 230 typically have a 50% duty cycle. Similar to the signal shown in Graph 232, standard digital circuits employ a 50% duty cycle, where the signal is high for half the time and low for the other half. This half-and-half split provides symmetrical timing for rising-edge and falling-edge operations.

Example Circuitry with Flip-Flop Having Fan-In Cone and Fan-Out Cone

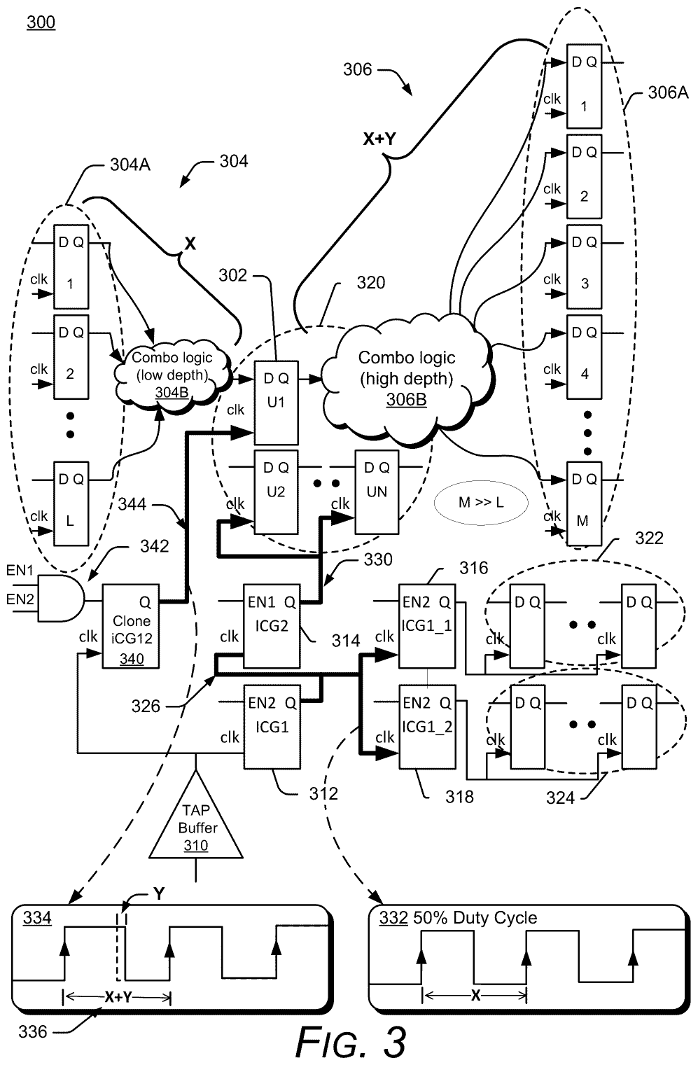

FIG. 3 illustrates an example of sequential logic circuitry 300 featuring a target flip-flop 302 with a low-depth fan-in cone 304 and a high-depth fan-out cone 306 suitable for implementing the technology described herein to reduce the clock logic depth by coalescing flip-flops with a low-depth fan-in cone and a high-depth fan-out cone. The sequential logic circuitry 300 addresses and solves a common timing problem that occurs with typical sequential logic circuitry, which features a flip-flop with minimal logic preceding it but extensive logic following it. The labeling conventions used with a typical sequential logic circuitry, as shown in FIG. 2, are also used for the sequential logic circuitry 300.

The target flip-flop 302 serves as the primary point of reference for discussing the operation of this sequential logic circuitry 300. The target flip-flop 302 features the low-depth fan-in cone 304 for its D input and the high-depth fan-out cone 306 for its Q output. While only one target flip-flop is depicted, other implementations may have a group of one or more target flip-flops.

In layout, the fan-in cone 304 and the fan-out cone 306 are the same as the fan-in cone 204 and the fan-out cone 206, respectively, of the typical sequential logic circuitry 200. As depicted, the fan-in cone 304 includes source flip-flops 304A, combinational logic 304B, and primary inputs that affect the data input D of the target flip-flop 302. The source flip-flops 304A are numbered 1−L, where L is more than two. The number L represents the effective depth or levels of flip-flops in the fan-in cone 304. More specifically, the fan-in cone 304 is described as having low depth because it contains minimal logic levels between source and destination points (e.g., source is flip-flops 304A and destination is input D of target flip-flop 302).

Like the fan-in cone 204, the fan-in cone 304 has a bracket labeled X for one clock period of a signal. The signal from the Q output of the target flip-flop 302 propagates through the fan-in cone 304 during one complete clock period. This is shown in a 50% Duty Cycle Graph 332. Note that the width of the full period of the signal is X.

The fan-out cone 306 includes the logic paths extending forward from the output Q of the target flip-flop 302. As depicted, the fan-out cone 306 includes destination flip-flops 306A, combinational logic 306B, and primary outputs affected by the output Q of the target flip-flop 302. The destination flip-flops 306A are numbered 1−M, where M is more than L. The number M represents the effective depth or levels of flip-flops in the fan-out cone 306.

With one or more implementations, the ratio of the depth difference of the low-depth fan-in cone (which is L) and the high-depth fan-out cone (which is M) is at least one order of magnitude or greater. That is, M is at least 10 times L. In other words, there are ten times as many levels of the fan-out cone 306 as there are levels of the fan-in cone 304. In other implementations, the ratios may be, for example, 5 to 1, 10 to 1, 50 to 1, 100 to 1, 1000 to 1, or greater.

More specifically, the fan-out cone 306 is described as high-depth because it contains numerous logic levels between source and destination points (e.g., source is output Q of target flip-flop 302 and destination includes flip-flops 306A).

The fan-out cone 306 has a bracket labeled X+Y for one clock period of a signal. As indicated in Graph 334, the signal from the Q output of the target flip-flop 302 propagates through the fan-out cone 306 during one complete clock signal period. However, because the path through the fan-out cone 306 includes many more layers of electronic components, the propagation takes longer.

To accommodate this, the technology described here adjusts the clock window to increase the duty cycle to approximately 60% or more. This is shown at 336 of Graph 334 where the X width of the clock period is skewed by a widening factor being indicated by Y. Thus, the clock period (X) is expanded by Y. This is done by skewing or expanding the high pulse. In so doing, the duty cycle is greater than 50%. It may be 55 percent or a greater percentage duty cycle. In this way, additional time is afforded for the signals to propagate through the fan-out cone 306 during the now widened high clock window.

With this arrangement, data arrives quickly at the target flip-flop 302 through the low-depth fan-in cone 304. After capture, signals travel through numerous logic gates of the high-depth fan-out cone 306 before reaching subsequent storage elements (e.g., flip-flops 306A). Digital circuits operate on clock cycles with strict timing requirements. All combinational logic between consecutive flip-flops completes processing within one clock period. With the widened high pulse side of the clock signal provided by the technology described herein, the signal has additional time to propagate through the extensive fan-out logic of the high-depth fan-out cone 306. Unlike the typical approach, the sequential logic circuitry 300 need not adjust to a slower frequency to accommodate the longest path of the high-depth fan-out cone 306.

The target flip-flop has a unit designation of “U1.” Indeed, it is one of a group 320 of linked flip-flops having a similar unit designation that starts with “U” followed by a numerical identifier. The letter “U” before flip-flop identifiers indicates a unit designation in circuit schematics. The U-labeling follows standard electronic component marking conventions. As shown, there are N U-labeled flip-flops, where N is a number greater than two.

The U-labeled flip-flops in FIG. 3 share a common source of their clock signal 308. Because of this, each of the U-labeled flip-flops is synchronized. This shared clock signal 308 ensures all connected flip-flops (e.g., U-labeled flip-flops) sample input data at the same moment. Each rising clock edge triggers the simultaneous capture of data across all connected components.

When components, such as the U-labeled flip-flops, have a common clock, timing boundaries for data processing operations are set. For example, all combinational logic between common-clocked flip-flops must complete calculations within one clock cycle. This synchronized organization creates a foundation for sequential operations where data moves through the circuit in coordinated steps defined by clock transitions.

The sequential logic circuitry 300 has a TAP (Test Access Port) buffer 310 connected to iCG1 312 and clone iCG12 340. The TAP 310 operates as a signal conditioning element, with its primary function being to receive input signals and produce strengthened output signals with maintained integrity. TAP buffers contain amplification circuitry to restore signal levels. The TAP buffer 310 strengthens the clock signal before delivery to the iCG1 312 and iCG clone 340. This arrangement ensures clock edges remain sharp with minimal degradation.

The iCG1 312 is an integrated clock gate (iCG), which receives two primary inputs: a clock signal from the TAP buffer 310 and an enable signal EN2. The enable signal EN2 determines whether the clock signal passes through the iCG1 312. When the enable signal EN2 is active, the iCG1 312 allows the clock signal to pass through to the output, which is labeled Q.

As depicted, Q output of the iCG1 312 distributes clock signals 326 to three secondary clock gates. These secondary gates include iCG2 314, iCG1_1 316, and iCG1_2 318. This arrangement forms a hierarchical clock distribution network. As the primary clock gate, the iCG1 312 controls whether any clock signals 326 reach the secondary gates. Each secondary gate then independently manages clock signal delivery to specific flip-flop groups. Each secondary gate contains a separate enable input. Clock signals pass through a secondary gate only under two conditions. First, the iCG1 312 supplies incoming clock pulses. Second, the secondary gate must receive an active enable signal. This multi-level topology provides graduated control over different circuit sections. The iCG1 312 enables or disables larger functional blocks. Secondary gates control smaller sub-sections within these blocks.

As depicted, the iCG2 314 manages clock signal 330 delivery to the U-labeled flip-flop group 320, but to the exclusion of the target flip-flop 302. That is, while all of the other U-labeled flip-flops of the group 320 receive the clock signal 330, the target flip-flop 302 does not. Instead, the target flip-flop 302 receives a different clock signal discussed below. Collectively, the U-labeled flip-flops-except—for the target flip-flop 302—may be considered a group of flip-flops.

The iCG2 314 receives an enable signal EN1 to determine whether the clock signal passes through it. The iCG1_1 316 is coupled to and drives (e.g., via clock signal delivery to) a group of multiple downstream flip-flops 322, and the iCG1_2 318 is coupled to and drives (e.g., via clock signal delivery to) a group of multiple downstream flip-flops 324. The enable signal EN1 determines whether the clock signal passes through the iCG1_1 (316) and iCG1_2 (318).

Control logic (not shown) of the sequential logic circuitry 300 generates the enable signals EN1 and EN2 based on circuit activity needs. The enable signal EN1 activates or deactivates the iCG2 314, iCG1_1 316, and iCG1_2 318. The enable signal EN2 activates or deactivates the iCG1 312. The Q output of the iCG1 312 transmits clock signals only when both the clock signal from the TAP buffer 310 and the enable signal EN2 are active.

Note that the iCG1 312, iCG1_1 316, and iCG1_2 318 share the same clock signal 326 and enable signal EN2. As such, these clock gates may be referred to as a cluster of multiple iCGs. Thus, the cluster of the iCG1 312, iCG1_1 316, and iCG1_2 may be described as being coupled to and driving two groups of multiple downstream flip-flops (e.g., group 322 and group 324). Alternatively, the two groups may be considered one large group of flip-flops. While no other clock gate shares the same clock and enable signals with the iCG2 314, the iCG2 318 may be described as a cluster of one.

The clone iCG12 340 is a clone of both the iCG1 312 and the iCG2 314. Typically, a clone iCG is a duplicate of an iCG that is created to distribute the load of the original iCG. As a duplicate, a typical clone iCG shares the same enable signal as the original iCG and thus performs the same gating function as that original iCG. However, the clone iCG12 340 is a “cross” clone of both the iCG1 312 and the iCG2 314. While no other clock gate shares the same clock and enable signals with the clone iCG12 340, the clone iCG12 may be described as a cluster of one.

As such, clone iCG12 340 shares the enable signal EN2 of the iCG1 312 and the enable signal EN1 of the iCG2 314. It does this by using a logical AND gate 342, which accepts both EN1 and EN2 as input. As such, the clone iCG12 340 receives an active enable signal when both EN1 and EN2 are active. Thus, when the clone iCG12 340 receives a clock signal and an active enable signal (when both EN1 and EN2 are active), then clock signal 344 is sent to the target flip-flop 302.

Consequently, the clone iCG12 340 coalesces with both the iCG1 312 and the iCG2 314 to drive the target flip-flop 302. The coalescing process involves merging the clock distribution paths, sharing the same enable signals (e.g., EN1 and EN2) across multiple clock gates, combining driving capabilities to enhance clock strength, and establishing a single point of control for clock delivery.

### Example Operation

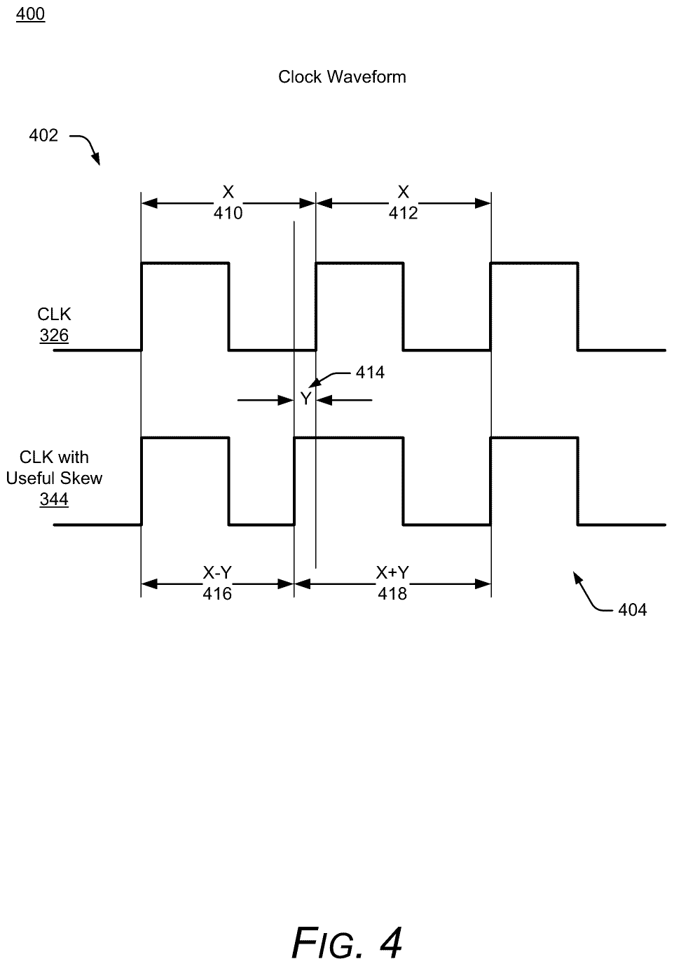

By referring to FIGS. 3 and 4, an example operation of the sequential logic circuitry 300—featuring the target flip-flop 302 with the low-depth fan-in cone 304 and the high-depth fan-out cone 306—is described. With the arrangement of the sequential logic circuitry 300 shown in FIG. 3 and described above, the sequential logic circuitry 300 utilizes the clone iCG12 340 to expand the clock window for the target flip-flop 302, enabling complete signal propagation across the fan-out cone 306 in a single clock cycle. This can be seen by comparing and contrasting example clock waveforms of FIG. 4.

FIG. 4 illustrates example clock waveforms 400 of clock signals that may be generated in accordance with the technology described herein. In particular, a waveform 402 represents the clock signal 326 that drives the iCG2 314, iCG1_1 316, and iCG1_2 318. The waveform 402 has a 50% duty cycle. As depicted, each complete cycle of the waveform 402 has a uniform width: X. This is shown at 410 and 412.

A waveform 404 represents the clock signal 344, which is output from the clone iCG12 340 and drives the target flip-flop 302. The sequential circuitry 300 applies a useful skew that expands the clock window for a single clock period when driving the fan-out cone 306. In particular, the arrangement with the clone iCG12 340 introduces the useful clock skew.

The useful clock skew creates an intentional timing difference between the clock signals 326 and 344. In particular, a useful skew may be employed that adjusts clock signal arrival at destination flip-flops (e.g., group 306A). This adjusted arrival provides additional time for data propagation between sequential elements. As a result, setup time violations decrease in critical paths. Clock Tree Synthesis tools may be employed to implement useful skews. Such tools include, for example, buffer size variations, wire length adjustments, and targeted load modifications.

The waveform 404 shows a largely 50% duty cycle, but a clock expands its window of one clock cycle by a pull factor of Y 414. This results in an expanded clock cycle 418, defined by X+Y. Following is a reduced cycle 416, which is reduced by the same pull factor Y 414; thus, the reduced clock 416 is defined by X-Y. The expanded clock cycle 418 has a 60% duty cycle.

### Example Method

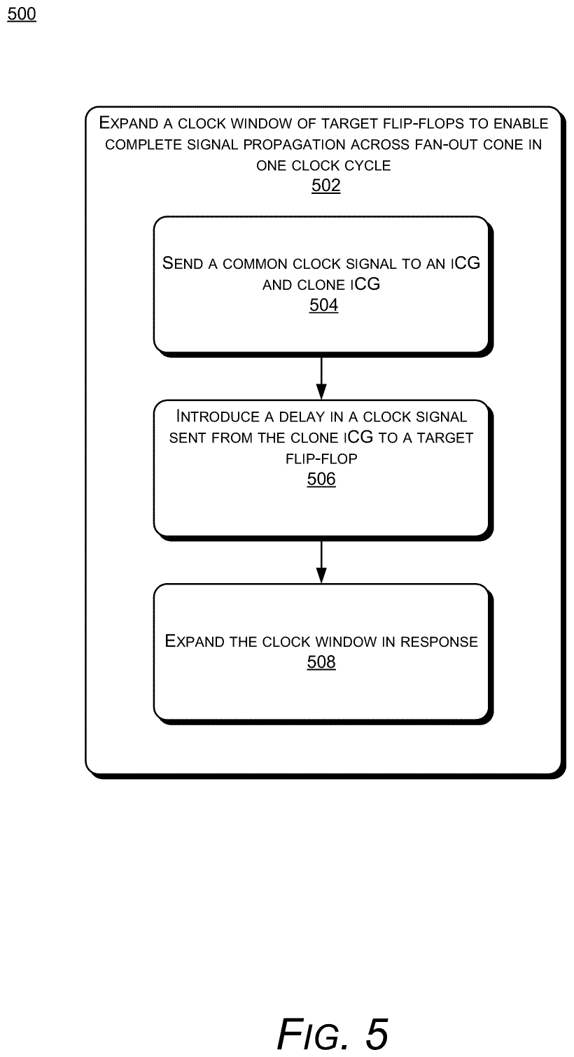

FIG. 5 illustrates an example method 500 for expanding the clock window to enable complete signal propagation across the fan-out cone in one clock cycle in accordance with one or more implementations described herein to reduce the clock logic depth of sequential logic circuitry in a digital circuit by coalescing flip-flops with a low-depth fan-in cone and a high-depth fan-out cone. The example method 500 is performed by a suitable digital circuit, such as that which includes sequential circuitry 300.

At 502, the sequential circuitry expands a clock window for the first group of one or more target flip-flops, enabling complete signal propagation across the fan-out cone in a single clock cycle. The following actions are part of block 502.

At 504, the sequential circuitry sends a common clock signal to an iCG and a clone iCG. The cluster receives this common clock signal if there are multiple clustered clock gates. A source of the common clock signal may be the TAP buffer 310.

At 506, the sequential circuitry reduces a delay in a clock signal sent from the clone iCGs to the target flip-flops. The sequential circuitry may pull the clock by removing one or more levels. This level removal becomes the clock pull for the target flip-flop.

As described in FIG. 4, the useful clock skew may reduce this delay.

At 508, in response to the introduced delay, the sequential circuitry expands the clock window to enable complete signal propagation across the fan-out cone in a single clock cycle.

### CONCLUSION

Although implementations of techniques for, and apparatuses enabling, an expansion of a clock window to enable complete signal propagation across a fan-out cone in one clock cycle have been described in language specific to features and/or methods, it is to be understood that the subject of the appended claims is not necessarily limited to the specific features or methods described. Rather, the specific features and methods are disclosed as example implementations expanding a clock window to enable complete signal propagation across a fan-out cone in one clock cycle.

What is claimed is:

1. Sequential logic circuitry comprising:
a first group of one or more flip-flops;
a first cluster of one or more integrated clock gates (iCGs) coupled to and driving the first group of flip-flops;
a first group of one or more target flip-flops, each target flip-flop having a low-depth fan-in cone and a high-depth fan-out cone; and
a first cluster of one or more clone iCGs coupled to the first group of target flip-flops and to the first cluster of one or more iCGs, the first cluster of one or more clone iCGs being configured to coalesce with the first cluster of one or more iCGs and driving the first group of one or more target flip-flops.

2. The sequential logic circuitry of claim 1, wherein the first cluster of one or more iCGs and the first cluster of one or more clone iCGs share a common clock signal and a common enable signal.

3. The sequential logic circuitry of claim 1, wherein a ratio of depth difference of the high-depth fan-out cone to the low-depth fan-in cone is at least one order of magnitude or greater.

4. The sequential logic circuitry of claim 1, wherein a ratio of depth difference of the high-depth fan-out cone to the low-depth fan-in cone is selected from a group consisting of 5 to 1, 10 to 1, 50 to 1, 100 to 1, 1000 to 1, or greater.

5. The sequential logic circuitry of claim 1 further comprising a Test Access Port (TAP) buffer coupled to and providing a clock input to the first cluster of one or more iCGs and the first cluster of one or more clone iCGs.

6. The sequential logic circuitry of claim 1 further comprising:
a second group of one or more flip-flops; and
a second cluster of one or more iCGs coupled to and driving the second group of one or more flip-flops, wherein:
the first cluster of one or more iCGs is configured to receive a first enable signal and the second cluster of one or more iCGs is configured to receive a second enable signal; and
the first cluster of one or more clone iCGs is configured to receive a logically ANDed first and second enable signals.

7. The sequential logic circuitry of claim 1, wherein an output signal from the first group of one or more target flip-flops sent through the fan-out cone in one clock cycle has a duty cycle of 60% or greater.

8. A method performed by sequential logic circuitry that includes a first group of one or more flip-flops; a first cluster of one or more integrated clock gates (iCGs) coupled to and driving the first group of flip-flops; a first group of one or more target flip-flops, each target flip-flop having a low-depth fan-in cone and a high-depth fan-out cone; and a first cluster of one or more clone iCGs coupled to the first group of target flip-flops and to the first cluster of one or more iCGs, the first cluster of one or more clone iCGs being configured to coalesce with the first cluster of one or more iCGs and driving the first group of one or more target flip-flops, the method comprising expanding a clock window for the first group of one or more target flip-flops to enable complete signal propagation across the fan-out cone in one clock cycle.

9. The method of claim 8 comprising:
sending a common clock signal to the first cluster of one or more iCGs and the first cluster of one or more clone iCGs;
reducing a delay in a clock signal sent from the first cluster of one or more clone iCGs to the first group of one or more target flip-flops; and
in response, expanding a clock window for the first group of one or more target flip-flops to enable complete signal propagation across the fan-out cone in one clock cycle.
